(19) United States
(12) Patent Application Publication
(10) Pub. No.: US 2023/0245948 A1
(43) Pub. Date: Aug. 3, 2023

(54) SEMICONDUCTOR DEVICE AND MANUFACTURING METHOD THEREOF

(71) Applicant: FUJI ELECTRIC CO., LTD., Kawasaki-shi (JP)

(72) Inventors: Takahiro KOYAMA, Matsumoto-city (JP); Hiromichi GOHARA, Matsumoto-city (JP)

(73) Assignee: FUJI ELECTRIC CO., LTD., Kawasaki-shi (JP)

(21) Appl. No.: 18/090,055

(22) Filed: Dec. 28, 2022

(30) Foreign Application Priority Data
Feb. 2, 2022 (JP) 2022-014626

(51) Int. Cl. H01L 23/433; H01L 23/495; H01L 23/40

(52) U.S. Cl. CPC H01L 23/4334; H01L 23/49575; H01L 23/49551; H01L 23/4006

(57) ABSTRACT

A semiconductor device includes a support, a semiconductor module, a heat transfer medium, and a first frame member. The semiconductor module includes a semiconductor chip and a resin member sealing the semiconductor chip, and is mounted on the support via the heat transfer medium. The first frame member is disposed on the semiconductor module. The first frame member has a first frame portion that covers an edge portion of an upper surface of the semiconductor module, and a first opening portion formed in the first frame portion for exposing the semiconductor module. The first frame member is fixed to the support by screws.

### CROSS-REFERENCE TO RELATED APPLICATION

This application is based upon and claims the benefit of priority of the prior Japanese Patent Application No. 2022-014626, filed on Feb. 2, 2022, the entire contents of which are incorporated herein by reference.

### BACKGROUND OF THE INVENTION

### 1. Field of the Invention

The embodiments discussed herein relate to a semiconductor device and a semiconductor device manufacturing method.

### 2. Background of the Related Art

There is known a technique about a power semiconductor device including: a case in which semiconductor elements mounted on a substrate are stored; and a base board. This power semiconductor device has attachment holes in four locations near four corners of the base board and in four locations each being near the center between two of the corners. According to this technique, by inserting screws into the attachment holes, the power semiconductor device is fixed to a heatsink via grease (Japanese Laid-open Patent Publication No. 2008-172146).

In addition, there is known a technique of fixing a semiconductor module to a cooler having a recess. A semiconductor package of the semiconductor module, a metal plate, and a spring that have through holes that overlap in plan view are sequentially arranged on the cooler via grease. According to this technique, the semiconductor module is fixed to the cooler by fastening a fixture screw that is inserted into the recess of the cooler through the group of through holes from above the spring (International Publication Pamphlet No. WO 2021/028965).

In addition, there is known a technique in which a heat radiation fin to which a ceramic board on which semiconductor components are mounted is fixed is covered by a metal or resin cap whose cross section has a hat shape. According to this technique, this cap is fixed to a housing by screws, by using attachment holes in flange portions that extend in longitudinal directions of the cap (Japanese Laid-open Patent Publication No. 05-315487). In addition, there is known a technique of forming a protruding portion inside the cap. The protruding portion is formed for bonding to the heat radiation fin via adhesive having good elasticity (Japanese Laid-open Patent Publication No. H05-315487).

In addition, there is known a technique about a semiconductor package mounting apparatus having a cavity in which a semiconductor package is stored and holes into which semiconductor package connection pins are inserted. There is also known a technique of fixing the mounting apparatus in which the semiconductor package is stored to a heat radiation structure (Japanese Laid-open Patent Publication No. 2020-145420). In addition, there is known a technique of forming a protruding portion for fixing the semiconductor package inside the cavity of the mounting apparatus. In addition, there is known a technique of forming openings for disposing structure mounting type temperature sensors thermally coupled to the semiconductor package in the mounting apparatus (Japanese Laid-open Patent Publication No. 2020-145420).

In addition, there is known a technique in which through holes are formed in a case that surrounds the outer periphery of a circuit board having one main surface on which semiconductor elements are mounted and having the other main surface fixed to a heatsink via silicon grease or the like. According to this technique, the case is fixed to the heatsink by inserting screws into the through holes (Japanese Laid-open Patent Publication No. 2015-122453). In addition, there is known a technique in which the case is provided with a pressing portion for pressing a peripheral portion of the circuit board when the case is fixed to the heatsink. In addition, there is known a technique in which a protruding portion for applying force toward the heatsink is formed at approximately the center of the circuit board when the case is fixed to the heatsink (Japanese Laid-open Patent Publication No. 2015-122453).

In addition, there is known a technique in which a case having an opening portion at its bottom portion is mounted on a work stage, and a package is mounted in the opening portion in the case on the work stage. According to this technique, the case has a first terminal having one end exposed to the outside at the bottom portion of the case and having the other end formed to extend to the outside of the case. The first terminal is bonded to a second terminal of the package, the second terminal being formed to extend along the bottom portion of the case, by using bonding material (International Publication Pamphlet No. WO 2013/171946). In addition, there is known a technique in which a partition is formed at an intermediate location in the depth direction inside the case, and the first terminal is located to be exposed to the outside on the lower surface of the partition. According to this technique, the package is mounted on the work stage by applying bonding material to the upper surface of the second terminal, the case is disposed on the package, and the first terminal is bonded on the second terminal via bonding material (International Publication Pamphlet No. WO 2013/171946).

In addition, there is known a technique in which sealing resin is pressed against and fixed to an external heat radiation fin. According to this technique, the sealing resin seals semiconductor elements and a lead frame to which the semiconductor elements are fixed, and a groove is formed in the sealing resin such that the sealing resin has a stepped upper surface, without forming any holes or cuts for inserting screws for fastening the sealing resin to the heat radiation fin in the sealing resin. One end portion of a clamper is engaged with the groove, and the other end portion is fixed to the heat radiation fin (Japanese Laid-open Patent Publication No. H09-199645).

In addition, there is known a technique in which a reinforcement beam is disposed on the upper surface of an individual semiconductor module, in which a semiconductor element is sealed by resin and which has a through hole, via a plate-like spring. According to this technique, a fixture screw is inserted into the through hole in the individual semiconductor module via the reinforcement beam and the corresponding plate-like spring from above the reinforcement beam such that the individual semiconductor module is fixed to a heat radiation board disposed on the lower surface of the individual semiconductor module, and a frame portion that surrounds the outer periphery of the individual semiconductor module is disposed on the heat radiation board (Japanese Laid-open Patent Publication No. 2008-258241). In addition, there is known a technique of fixing the reinforcement beam to the frame portion (Japanese Laid-open Patent Publication No. 2009-43863).

In addition, there is known a technique in which an individual semiconductor module having a heat radiation metal on its rear surface is disposed on a metal plate bonded inside a concave portion of a heatsink via heat radiation grease between the heat radiation metal and the metal plate. According to this technique, a spring pressing bracket is disposed on the upper portion of the semiconductor module via a plate spring, and the spring pressing bracket is fastened and fixed to the heatsink by screws (Japanese Laid-open Patent Publication No. 2014-225571).

In addition, there is known a technique in which an individual power semiconductor module in which a semiconductor device is sealed is mounted on a mounting surface of a heat radiation device by using a frame as a guide member via a heat transfer resin layer, a drive circuit unit is mounted on the individual power semiconductor module via a heat insulation sheet, a pressing plate, and a heat radiation sheet sequentially, and these elements are collectively fixed to the frame by using fixtures such as screws (Japanese Laid-open Patent Publication No. 2017-212286).

In addition, there is known a technique about a semiconductor device having a structure in which a supporting member, a cooling plate, semiconductor modules, a metal plate, a control substrate are stacked in this order. The cooling plate and the metal plate are fixed together to the supporting member by fastening screws, and the control substrate is fixed to the metal plate (Japanese Laid-open Patent Publication No. 2021-118657).

A semiconductor module having semiconductor chips and a resin member such as sealing resin that seals the semiconductor chips or a resin case is attached to a support such as a heat radiation board, a heatsink, a cooler, or a housing via a heat transfer medium such as heat radiation grease, for example. As a technique for attaching the semiconductor module to the support, there is known a technique of directly fixing or fastening the semiconductor module to the support by a screw, by forming a hole or a cut in the resin member of the semiconductor module and screwing the screw inserted into the hole or the cut into the support.

However, according to the technique of directly fixing a semiconductor module to a support by using a screw, if warpage occurs in the semiconductor module at the time of manufacturing or the like, when the semiconductor module is fixed to the support by the screw, the semiconductor module could be fixed to the support obliquely. If the semiconductor module is fixed to the support obliquely, a defect could occur in the wiring connection between the semiconductor module and another component. In addition, according to the technique of directly fixing a semiconductor module to a support by a screw, the semiconductor module could be deformed by the heat generated during its operation, and the resin member could be consequently destructed. In another case, due to pump-out of the heat radiation grease between the semiconductor module and the support, the heat radiation performance could deteriorate, and a malfunction could occur.

According to the technique of directly fixing a semiconductor module to a support by a screw, there is a possibility that a semiconductor device including the semiconductor module mounted on the support via a heat transfer medium could have insufficient performance and quality. According to other conventional techniques, the same problems could also occur. Other conventional techniques could also result in size increase, weight increase, cost increase, etc.

### SUMMARY OF THE INVENTION

In one aspect of the embodiments, there is provided a semiconductor device including: a support; a semiconductor module mounted on the support, the semiconductor module including a semiconductor chip and a resin member that seals the semiconductor chip; a heat transfer medium disposed between the support and the semiconductor module; and a first frame member disposed on the semiconductor module, the first frame member having: a first frame portion that covers an edge portion of an upper surface of the resin member, the first frame member being fixed to the support; and a first opening portion that is formed in the first frame portion, and through which the resin member is exposed.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF THE DRAWINGS

FIGS. 1A to 1C illustrate an example of a semiconductor device according to a first embodiment;

FIGS. 2A and 2B illustrate examples of a semiconductor module;

FIGS. 3A and 3B illustrate a structure example of a semiconductor module used in a semiconductor device according to the first embodiment;

FIGS. 4A and 4B are drawings illustrating a first structure example of the semiconductor device according to the first embodiment;

FIGS. 5A and 5B are other drawings illustrating the first structure example of the semiconductor device according to the first embodiment;

FIGS. 6A and 6B are drawings illustrating a second structure example of the semiconductor device according to the first embodiment;

FIGS. 7A to 7C illustrate an example of a semiconductor device according to a second embodiment;

FIGS. 8A and 8B are drawings illustrating a structure example of a semiconductor device according to the second embodiment;

FIGS. 9A and 9B are other drawings illustrating the structure example of the semiconductor device according to the second embodiment;

FIGS. 10A to 10C illustrate an example of a semiconductor device according to a third embodiment;

FIG. 11 illustrates a structure example of a semiconductor device according to the third embodiment;

FIG. 12 is a drawing illustrating a structure example of a semiconductor device according to a fourth embodiment;

FIG. 13 is another drawing illustrating the structure example of the semiconductor device according to the fourth embodiment;

FIG. 14 illustrates a structure example of a semiconductor device according to a fifth embodiment;

FIGS. 15A to 15C each illustrate an example of the connection between an external connection terminal and a terminal block of the semiconductor device according to the fifth embodiment; and

FIG. 16 illustrates an example of a semiconductor device manufacturing method according to a sixth embodiment.

### DETAILED DESCRIPTION OF THE INVENTION

### First Embodiment

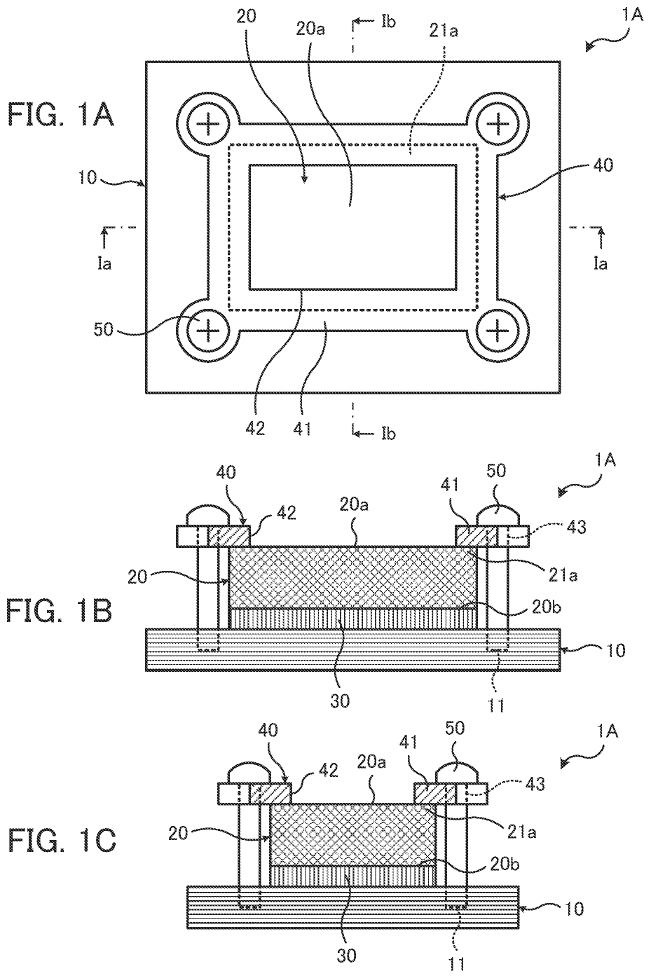

FIGS. 1A to 1C illustrate an example of a semiconductor device according to a first embodiment. FIG. 1A is a schematic plan view of a main part of an example of a semiconductor device. FIG. 1B is a schematic sectional view taken along a line Ia-Ia in FIG. 1A. FIG. 1C is a schematic sectional view taken along a line Ib-Ib in FIG. 1A.

A semiconductor device 1A in FIGS. 1A to 1C includes a support 10, a semiconductor module 20, a heat transfer medium 30, a first frame member 40, and screws 50.

A heat radiation board, a heatsink, a cooler, a housing, or the like is used as the support 10. A component having good thermal conductivity is used as the support 10. The support 10 has a predetermined number of screw holes 11 at predetermined locations. In FIGS. 1A to 1C, as an example, the support 10 has four screw holes 11 outside an area where the semiconductor module 20 is mounted.

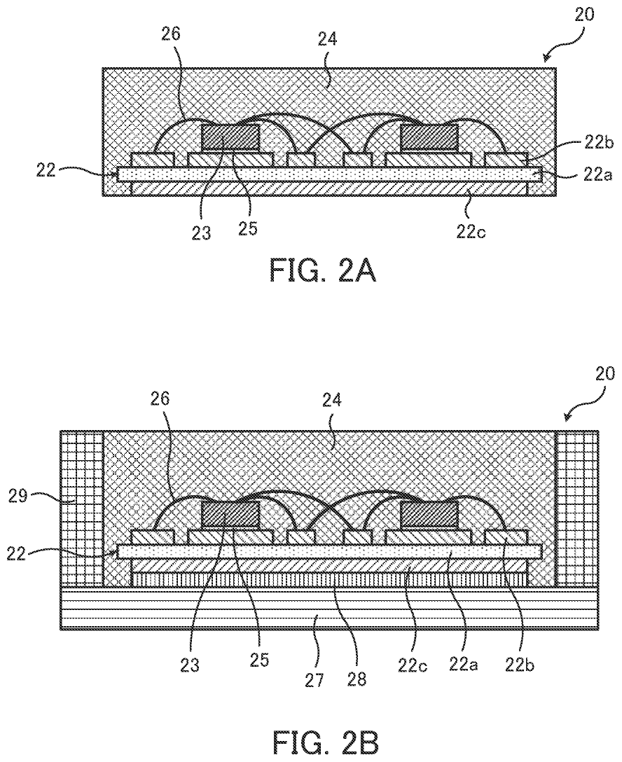

The semiconductor module 20 is mounted on the support 10. The semiconductor module 20 includes semiconductor chips and a resin member that seals the semiconductor chips. Structure examples of the semiconductor module 20 will be described below (FIGS. 2A and 2B). The screw holes 11 in the support 10 are formed outside the semiconductor module 20 mounted on the support 10.

The heat transfer medium 30 is disposed between the support 10 and the semiconductor module 20. A component having good thermal conductivity, such as heat radiation grease or a heat radiation sheet, is used as the heat transfer medium 30. The heat generated by the semiconductor module 20 (the semiconductor chips therein) during the operation of the semiconductor device 1A is transferred to the support 10, for example, via the heat transfer medium 30 and is released. The heat radiation path of the heat generated by the semiconductor module 20 is not limited to this path.

The first frame member 40 is disposed on the semiconductor module 20 and is fixed to the support 10. A material having certain stiffness, such as at least one of metal, ceramic, and resin materials or a combination of two or more of these kinds, is used for the first frame member 40. The first frame member 40 includes a first frame portion 41 and a first opening portion 42 formed inside the first frame portion 41. The first frame portion 41 has a frame-like shape that covers an edge portion 21a of an upper surface 20a of the semiconductor module 20. The first opening portion 42 communicates with the upper surface 20a of the semiconductor module 20. The first frame member 40 also has first insertion holes 43 that connect to the first frame portion 41. The first insertion holes 43 are formed to face the screw holes 11 in the support 10.

Small screws, bolts, or the like are used as the screws 50. The screws 50 are inserted into the first insertion holes 43 in the first frame member 40 from above the first frame member 40 (from an opposite direction of the support 10), and tip portions of the screws 50 are screwed into the screw holes 11 in the support 10. Because head portions of the screws 50 screwed into the screw holes 11 press the outer edges of the first insertion holes 43, the first frame member 40 is fixed to the support 10.

In the case of the semiconductor device 1A, the first frame portion 41 of the first frame member 40 fixed to the support 10 by the screws 50 outside the semiconductor module 20 presses the edge portion 21a of the upper surface 20a of the semiconductor module 20 toward the support 10. As a result, the semiconductor module 20 is fixed to the support 10 via the heat transfer medium 30 disposed under a lower surface 20b of the semiconductor module 20.

FIGS. 2A and 2B illustrate examples of a semiconductor module. FIG. 2A is a schematic sectional view of a main part of a first example of a semiconductor module. FIG. 2B is a schematic sectional view of a main part of a second example of the semiconductor module.

A semiconductor module 20 illustrated in FIG. 2A includes an insulated circuit board 22, semiconductor chips 23, and sealing resin 24 (a resin member).

The insulated circuit board 22 includes an insulating board 22a such as a ceramic board and a first conductive layer 22b and a second conductive layer 22c, which are made of copper and formed on two main surfaces of the insulating board 22a. The first conductive layer 22b is formed as predetermined patterns. For example, a direct copper bonding (DCB) substrate or an active metal brazed (AMB) substrate is used as the insulated circuit board 22.

The semiconductor chips 23 are mounted on the first conductive layer 22b of the insulated circuit board 22. Semiconductor chips such as insulated gate bipolar transistors (IGBTs) or metal-oxide-semiconductor field-effect transistors (MOSFETs) are used as the semiconductor chips 23. The semiconductor chips 23 are electrically connected to the first conductive layer 22b of the insulated circuit board 22 by using, for example, bonding material 25 such as solder or sintered material and wires 26.

The sealing resin 24 is formed to seal the insulated circuit board 22, the semiconductor chips 23 mounted thereon, the bonding material 25, the wires 26, etc. In the case of the semiconductor module 20 illustrated in FIG. 2A, the second conductive layer 22c of the insulated circuit board 22 is exposed to the outside from the sealing resin 24, the second conductive layer 22c being located in an opposite direction of the first conductive layer 22b on which the semiconductor chips 23 are mounted. While not illustrated, external connection terminals such as a positive terminal, a negative terminal, an output terminal, and control terminals electrically connected to the semiconductor chips 23 and the insulated circuit board 22 inside the sealing resin 24 are formed to extend to the outside of the sealing resin 24 of the semiconductor module 20 illustrated in FIG. 2A.

The sealing resin 24 of the semiconductor module 20 illustrated in FIG. 2A is an example of a resin member that seals the semiconductor chips 23, etc.

A semiconductor module 20 illustrated in FIG. 2B includes a heat radiation board 27, a heat transfer medium 28, an insulated circuit board 22, semiconductor chips 23, sealing resin 24 (a resin member), and a resin case 29 (a resin member).

A metal plate, e.g., a copper plate, is used as the heat radiation board 27. The insulated circuit board 22 on which the semiconductor chips 23 have been mounted is disposed on the heat radiation board 27 via the heat transfer medium 28 such as heat radiation grease or a heat radiation sheet. The semiconductor chips 23 are electrically connected to a first conductive layer 22b of the insulated circuit board 22 by using, for example, bonding material 25 and wires 26. A second conductive layer 22c of the insulated circuit board 22 is connected to the heat radiation board 27 via the heat transfer medium 28, the second conductive layer 22c being located in an opposite direction of the first conductive layer 22b on which the semiconductor chips 23 are mounted.

The resin case 29 is disposed on the heat radiation board 27 such that the resin case 29 surrounds the insulated circuit board 22 on which the semiconductor chips 23 are mounted. The resin case 29 is fixed to the heat radiation board 27 by using adhesive, screws, or the like not illustrated. The sealing resin 24 is formed inside the space surrounded by the resin case 29. The insulated circuit board 22 disposed on the heat radiation board 27, the semiconductor chips 23 mounted on the insulated circuit board 22, the bonding material 25, the wires 26, the heat transfer medium 28, etc. are sealed by the resin case 29 and the sealing resin 24 formed inside the space surrounded by the resin case 29. While not illustrated, external connection terminals such as a positive terminal, a negative terminal, an output terminal, and control terminals electrically connected to the semiconductor chips 23 and the insulated circuit board 22 in the sealing resin 24 are formed to extend to the outside of the sealing resin 24 and the resin case 29 of the semiconductor module 20 illustrated in FIG. 2B.

The sealing resin 24 and the resin case 29 of the semiconductor module 20 illustrated in FIG. 2B are each an example of a resin member that seals the semiconductor chips 23, etc.

For example, the semiconductor module 20 as illustrated in FIG. 2A or 2B is sandwiched and fixed between the support 10 and the first frame member 40 by the first frame member 40 fixed to the support 10 by the screws 50, as in the semiconductor device 1A illustrated in FIGS. 1A to 1C.

For example, if the semiconductor module 20 as illustrated in FIG. 2A is used for the semiconductor device 1A (FIGS. 1A to 1C), the second conductive layer 22c of the insulated circuit board 22, the second conductive layer 22c being exposed to the outside from the sealing resin 24, is oriented toward the support 10, and the semiconductor module 20 is fixed to the support 10 via the heat transfer medium 30 disposed between the second conductive layer 22c and the support 10. The first frame member 40 is disposed such that the first frame portion 41 covers an edge portion of the upper surface of the sealing resin 24, which is the resin member, the edge portion corresponding to the edge portion 21a of the upper surface 20a of the semiconductor module 20. The first opening portion 42 of the first frame member 40 communicates with the sealing resin 24 inside the first frame portion 41. The first frame member 40 and the semiconductor module 20 are disposed such that the first insertion holes 43 in the first frame member 40 whose first frame portion 41 covers the edge portion of the upper surface of the sealing resin 24 face the screw holes 11 in the support 10. By inserting the screws 50 into the first insertion holes 43 in the first frame member 40 and screwing tip portions of the screws 50 into the screw holes 11 in the support 10, the first frame member 40 is fixed to the support 10, and the semiconductor module 20 is consequently fixed to the support 10 via the heat transfer medium 30.

For example, if the semiconductor module 20 as illustrated in FIG. 2B is used for the semiconductor device 1A (FIGS. 1A to 1C), the heat radiation board 27 on which the sealing resin 24 and the resin case 29 are formed is oriented toward the support 10, and the semiconductor module 20 is fixed to the support 10 via the heat transfer medium 30 disposed between the heat radiation board 27 and the support 10. The first frame member 40 is disposed such that the first frame portion 41 covers an edge portion of the upper surface of the sealing resin 24 as a resin member and the upper surface of the resin case 29 as a resin member, these covered portions corresponding to the edge portion 21a of the upper surface 20a of the semiconductor module 20, or such that the first frame portion 41 covers the upper surface of the resin case 29 or an edge portion of this upper surface, the covered portion corresponding to the edge portion 21a of the upper surface 20a of the semiconductor module 20. The first opening portion 42 in the first frame member 40 communicates with the sealing resin 24 inside the first frame portion 41 or communicates with the sealing resin 24 and the resin case 29. The first frame member 40 and the semiconductor module 20 are disposed such that the first insertion holes 43 in the first frame member 40 whose first frame portion 41 covers the edge portion of the upper surface of the sealing resin 24 and the upper surface of the resin case 29 or the upper surface of the resin case 29 or an edge portion of this upper surface face the screw holes 11 in the support 10. By inserting the screws 50 into the first insertion holes 43 in the first frame member 40 and screwing the tip portions of the screws 50 into the screw holes 11 in the support 10, the first frame member 40 is fixed to the support 10, and the semiconductor module 20 is consequently fixed to the support 10 via the heat transfer medium 30.

As described above, in the case of the semiconductor device 1A illustrated in FIGS. 1A to 1C, the semiconductor module 20 is fixed to the support 10 by using the first frame member 40 having the first frame portion 41 that covers the edge portion 21a of the upper surface 20a of the semiconductor module 20. The first frame member 40 is fixed to the support 10 by using the screws 50 inserted into the first insertion holes 43 in the first frame member 40. Because the first frame portion 41 of the first frame member 40 presses the edge portion 21a of the upper surface 20a of the semiconductor module 20 toward the support 10, the semiconductor module 20 is fixed to the support 10.

In the case of the semiconductor device 1A having the above structure, because the first frame portion 41 of the first frame member 40 presses the edge portion 21a of the upper surface 20a of the semiconductor module 20, the stress that occurs in the semiconductor module 20 is reduced and distributed more, as compared with the conventional techniques, that is, the conventional techniques in which holes or cuts are formed in a resin member of a semiconductor module, and screws inserted into the holes or cuts are screwed into a support, so as to directly fix the semiconductor module to the support by the screws. Thus, the stress caused by thermal deformation of the semiconductor module 20 that could occur by the temperature change at the time of assembly of the semiconductor device LA, the temperature change during an operation, the temperature change of the outside environment, etc. is reduced and distributed. Therefore, destruction of the semiconductor module 20 is prevented.

In addition, in the case of a conventional technique of directly fixing a semiconductor module to a support by a screw, if warpage occurs in the semiconductor module at the time of manufacturing or the like, when the semiconductor module is fixed to the support by the screw, the semiconductor module could be fixed to the support obliquely, and a defect could occur in the wiring connection between the semiconductor module and another component. However, in the case of the semiconductor device 1A manufactured by the technique in which the semiconductor module 20 is fixed by using the above first frame member 40, since the first frame portion 41 of the first frame member 40 presses the edge portion 21a of the upper surface 20a of the semiconductor module 20, obliquely fixing the semiconductor module 20 and occurrence of a resultant defect in the wiring connection are prevented.

In addition, compared with a conventional technique of directly fixing a semiconductor module to a support by a screw, the semiconductor device 1A achieves less occurrence of torque reduction with respect to the semiconductor module 20 fixed onto the support 10 via the heat transfer medium 30 such as heat radiation grease. Thus, pump-out of the heat transfer medium 30 between the semiconductor module 20 and the support 10, and resultant deterioration in heat radiation performance are prevented. As a result, occurrence of a malfunction caused by overheat of the semiconductor module 20 is prevented.

In addition, since there is no need to form screw insertion holes or cuts in the semiconductor module 20 of the semiconductor device 1A, the manufacturing cost of the semiconductor module 20 and the manufacturing cost of the semiconductor device 1A including the semiconductor module 20 are reduced. In addition, since there is no need to form screw insertion holes or cuts in the semiconductor module 20 of the semiconductor device 1A, instead of improving the strength of portions around such holes or cuts, the strength of portions around the first frame member 40 or the first insertion holes 43 is improved. In this way, the fixing of the first frame member 40 and the semiconductor module 20 to the support 10 is enhanced.

The first embodiment realizes the high-performance and high-quality semiconductor device 1A including the semiconductor module 20 mounted on the support 10 via the heat transfer medium 30.

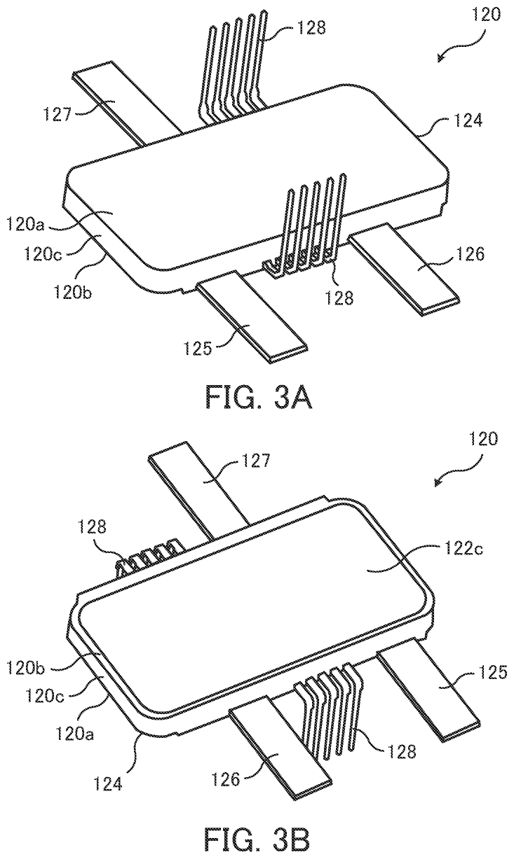

Next, more specific structure examples of the semiconductor device 1A as described above will be described with reference to FIGS. 3A to 5B.

FIGS. 3A and 3B illustrate a structure example of a semiconductor module used in a semiconductor device according to the first embodiment. FIG. 3A is a schematic perspective view of a main part of an example of a semiconductor module when the semiconductor module is seen from one side. FIG. 3B is a schematic perspective view of the main part of the example of the semiconductor module when the semiconductor module is seen from the other side.

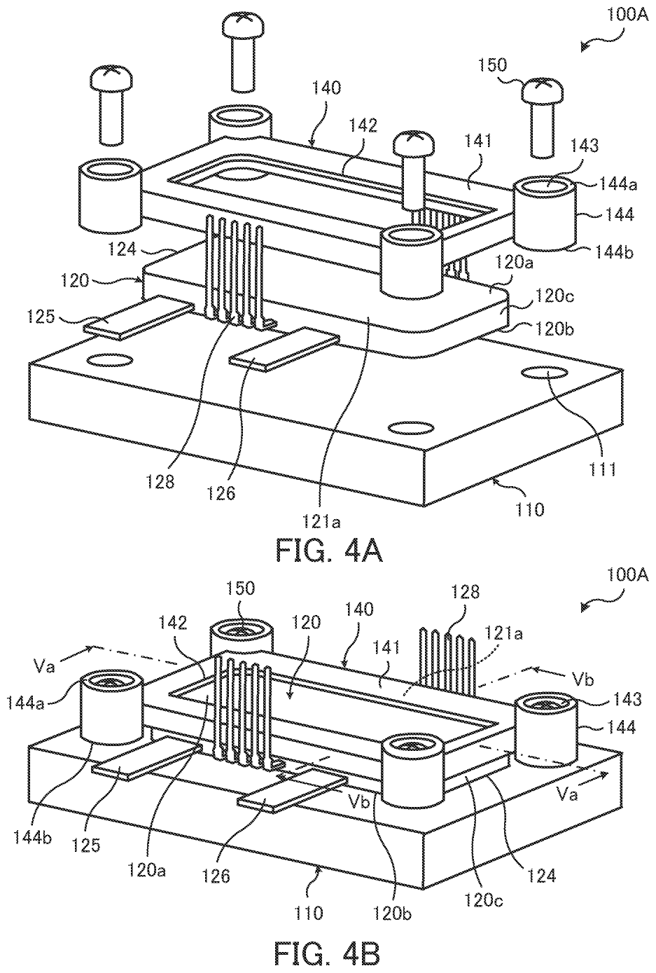

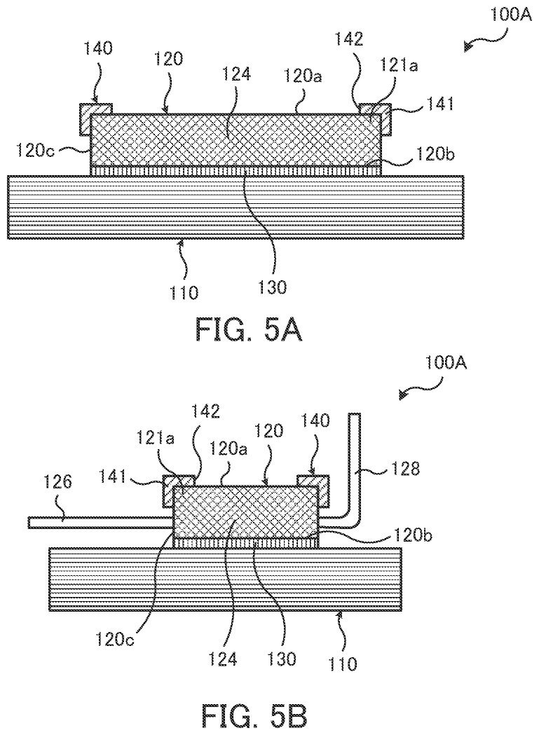

In addition, FIGS. 4A and 4B and FIGS. 5A and 5B illustrate a first structure example of a semiconductor device according to the first embodiment. FIG. 4A is a schematic exploded perspective view of a main part of an example of a semiconductor device. FIG. 4B is a schematic perspective view of the main part of the example of the semiconductor device. FIG. 5A is a schematic sectional view taken along a line Va-Va in FIG. 4B. FIG. 5B is a schematic sectional view taken along a line Vb-Vb in FIG. 4B.

FIGS. 3A and 3B illustrate an example of a semiconductor module 120. The semiconductor module 120 includes a resin member 124 and a positive terminal 125, a negative terminal 126, an output terminal 127, and control terminals 128 that extend to the outside of the resin member 124.

An insulated circuit board and semiconductor chips such as IGBTs mounted on the insulated circuit board, which are not illustrated, are formed in the resin member 124 of the semiconductor module 120. The insulated circuit board and the semiconductor chips are sealed by the resin member 124 such that a conductive layer 122c formed on one main surface of the insulated circuit board is exposed to the outside from the resin member 124, the main surface being located in an opposite direction of the other main surface on which the semiconductor chips are mounted.

The positive terminal 125, the negative terminal 126, the output terminal 127, and the control terminals 128 are formed such that these terminals are electrically connected to the insulated circuit board and the semiconductor chips formed inside the resin member 124. For example, the positive terminal 125, the negative terminal 126, and the output terminal 127 are formed to extend to the outside from a side surface 120c connecting an upper surface 120a of the semiconductor module 120 (the upper surface of the resin member 124) and a lower surface 120b (the surface near the conductive layer 122c exposed from the resin member 124) of the semiconductor module 120, the upper surface 120a and the lower surface 120b being located in opposite directions. These terminals 125, 126, and 127 extend in lateral directions of the semiconductor module 120. For example, the control terminals 128 first extend a lateral direction from the side surface 120c of the semiconductor module 120 and are next bent and extend in the upward direction of the semiconductor module 120.

For example, the semiconductor module 120 may be formed as a so-called 2-in-1 IGBT module including a group of semiconductor chips constituting upper and lower arms in a power conversion apparatus.

The semiconductor module 120 as illustrated in FIGS. 3A and 3B is mounted on a support 110 such that the lower surface 120b faces the support 110, as illustrated in FIG. 4A. A heat transfer medium 130 such as heat radiation grease (FIGS. 5A and 5B) is disposed between the semiconductor module 120 and the support 110. The support 110 has screw holes 111 located outside the resin member 124 of the semiconductor module 120 mounted. As illustrated in FIG. 4A, a first frame member 140 is disposed on the semiconductor module 120 mounted on the support 110. A material such as a metal material having certain stiffness is used for the first frame member 140. The first frame member 140 has a first frame portion 141 that covers an edge portion 121a of the upper surface 120a of the semiconductor module 120, a first opening portion 142 located inside the first frame portion 141, and first fastener portions 144 having first insertion holes 143. The first insertion holes 143 in the first frame member 140 are formed to face the screw holes 111 in the support 110. As illustrated in FIG. 4A, screws 150 are inserted into the first insertion holes 143 from above the first frame member 140 and are screwed into the screw holes 111 in the support 110. As a result, a semiconductor device 100A as illustrated in FIG. 4B, that is, a semiconductor device 100A having the first frame member 140 fixed to the support 110 and having the semiconductor module 120 fixed by the first frame member 140 to the support 110, is obtained.

As illustrated in FIGS. 4A and 4B and FIGS. 5A and 5B, in the case of the semiconductor device 100A, the first frame portion 141 of the first frame member 140, the first frame portion 141 covering the edge portion 121a of the semiconductor module 120, has such a shape that covers part of the upper surface 120a (also referred to as the upper surface 120a of the resin member 124) and the side surface 120c (also referred to as the side surface 120c of the resin member 124) of the semiconductor module 120.

In addition, as illustrated in FIGS. 4A and 4B, in the case of the semiconductor device 100A, the individual first fastener portion 144 of the first frame member 140, the individual first fastener portion 144 having a corresponding first insertion hole 143, has an upper end 144a that protrudes to a location above the first frame portion 141 and a lower end 144b that protrudes to a location below the first frame portion 141, for example.

In addition, when the screws 150 are screwed into the screw holes 111 via the first insertion holes 143, as illustrated in FIG. 4B, the lower ends 144b of the first fastener portions 144 come into contact with the support 110 while the first frame portion 141 of the first frame member 140 does not come into contact with the positive terminal 125, the negative terminal 126, the output terminal 127, and the control terminals 128 extending from the side surface 120c of the semiconductor module 120 (FIGS. 4A and 4B and FIGS. 5A and 5B). In a case where an electrically conductive material such as a metal material is used for the first frame member 140, too, when the first frame member 140 is fixed to the support 110 by the screws 150, the electrical connection between the first frame member 140 and the positive terminal 125, the negative terminal 126, the output terminal 127, and the control terminals 128 is avoided.

The first frame portion 141 of the first frame member 140 may be formed to have such a shape that entirely covers the side surface 120c of the semiconductor module 120, excepting the areas from which the positive terminal 125, the negative terminal 126, the output terminal 127, and the control terminals 128 extend. The electrical connection between the first frame member 140 and the positive terminal 125, the negative terminal 126, the output terminal 127, and the control terminals 128 may be avoided in this way.

As illustrated in FIG. 4B and FIGS. 5A and 5B, by using the first frame member 140 fixed to the support 110 by the screws 150, the semiconductor module 120 is fixed to the support 110 via the heat transfer medium 130. For example, the screws 150 fixing the first frame member 140 to the support 110 are inserted into the first insertion holes 143 such that the screws 150 do not protrude from the upper ends 144a of the first fastener portions 144 of the first frame member 140. The screws 150 are screwed into the screw holes 111 in the support 110, press the first fastener portions 144 of the first frame member 140 toward the support 110, and fix the first frame member 140 to the support 110.

In the same way as described with the above semiconductor device 1A, compared with the case in which the conventional technique of directly fixing a semiconductor module to a support by a screw is used, the stress that is caused by the heat or the like and that occurs in the semiconductor module 120 of the semiconductor device 100A is reduced and distributed more, and as a result, destruction of the semiconductor module 120 is prevented. In addition, obliquely fixing the semiconductor module 120 and occurrence of a resultant defect in the wiring connection are prevented. In addition, torque reduction with respect to the semiconductor module 120 fixed onto the support 110 via the heat transfer medium 130 such as heat radiation grease, pump-out of the heat transfer medium 30, resultant deterioration in heat radiation performance, and overheat of the semiconductor module 20 are prevented.

In addition, in the case of the semiconductor device 100A, since the first frame portion 141 of the first frame member 140 covers the upper surface 120a and the side surface 120c of the resin member 124 around the edge portion 121a of the semiconductor module 120, displacement of the semiconductor module 120 in the upper and lateral directions is effectively prevented. By disposing the first frame member 140 covering the upper surface 120a and the side surface 120c of the resin member 124 around the edge portion 121a of the semiconductor module 120 such that the first insertion holes 143 face the screw holes 111 in the support 110, the locations of the semiconductor module 120 and the first frame member 140 with respect to the support 110 are defined.

In addition, in the same way as described with the above semiconductor device 1A, since there is no need to form screw insertion holes or cuts in the semiconductor module 120, the manufacturing cost of the semiconductor module 120 and the manufacturing cost of the semiconductor device 100A including the semiconductor module 120 are reduced. In the case of the semiconductor device 100A, by using a material such as a metal material having good stiffness for the first frame member 140 and by improving the strength of the first frame member 140 or the first fastener portions 144, the fixing of the first frame member 140 and the semiconductor module 120 to the support 110 is enhanced.

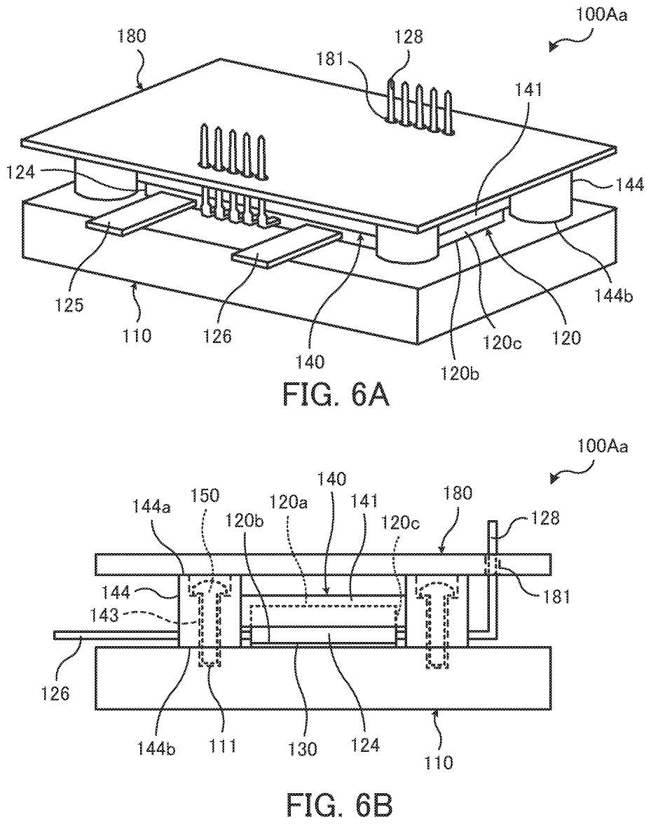

FIGS. 6A and 6B illustrate a second structure example of a semiconductor device according to the first embodiment. FIG. 6A is a schematic perspective view of a main part of an example of a semiconductor device. FIG. 6B is a schematic side view of the main part of the example of the semiconductor device.

A semiconductor device 100Aa illustrated in FIGS. 6A and 6B differs from the above semiconductor device 100A (FIGS. 4A and 4B and FIGS. 5A and 5B) in that the semiconductor device 100Aa includes a circuit board 180 on the first frame member 140.

Any one of various kinds of circuit boards, for example, a printed board, having predetermined wiring patterns on one side or two sides thereof is used as the circuit board 180. While not illustrated, various kinds of electronic components, for example, semiconductor chips, capacitors, resistors, and inductors, which are electrically connected to the wiring patterns of the circuit board 180, may be mounted on the circuit board 180.

As illustrated in FIGS. 6A and 6B, the circuit board 180 disposed on the first frame member 140 (in an opposite direction of the support 110) is into contact with the upper ends 144a of the first fastener portions 144 of the first frame member 140. Since the screws 150 that fix the first frame member 140 to the support 110 do not protrude from the upper ends 144a of the first fastener portions 144, the circuit board 180 comes into contact with the upper ends 144a of the first fastener portions 144. In addition, since the upper end 144a of the individual first fastener portion 144 protrudes to a location above the first frame portion 141, a predetermined gap is maintained between the circuit board 180 that is into contact with the upper ends 144a of the first fastener portions 144 and the first frame portion 141. The circuit board 180 is fixed to the first frame member 140 by using screws not illustrated, for example.

The circuit board 180 has through holes 181 into which the control terminals 128 are insertable at locations corresponding to the control terminals 128 of the semiconductor module 120. The control terminals 128 of the semiconductor module 120 are inserted into the through holes 181 in the circuit board 180, and the circuit board 180 is disposed on the first frame member 140 such that the circuit board 180 comes into contact with the upper ends 144a of the first fastener portions 144 of the first frame member 140 and is fixed to the first frame member 140 by using screws. The control terminals 128 inserted into the through holes 181 in the circuit board 180 are electrically connected to the wiring patterns of the circuit board 180. Control signals are supplied from the circuit board 180 to the semiconductor module 120 through the control terminals 128.

The semiconductor device 100Aa as illustrated in FIGS. 6A and 6B, that is, the semiconductor device 100Aa in which the circuit board 180 having wiring patterns electrically connected to the control terminals 128 of the semiconductor module 120 on the first frame member 140, is obtained. The semiconductor device 100Aa provides the same advantageous effects as those provided by the above semiconductor device 100A (FIGS. 4A and 4B and FIGS. 5A and 5B).

In the above examples, the first frame member 140 is fixed to the support 110 by the screws 150. Alternatively, the first frame member 140 may be fixed to the support 110 by welding, adhesive, or the like.

### Second Embodiment

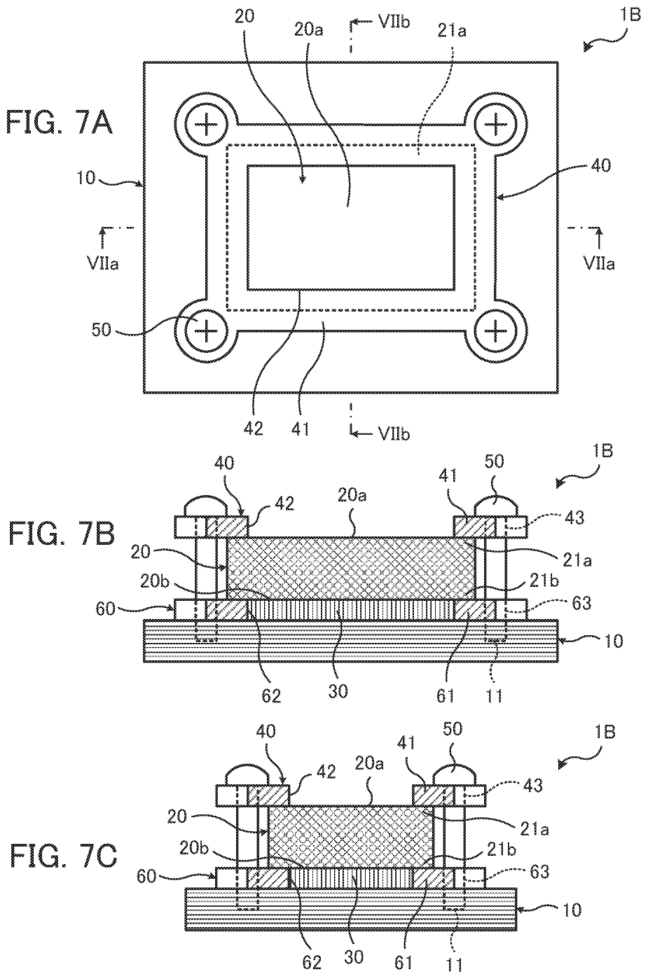

FIGS. 7A to 7C illustrate an example of a semiconductor device according to a second embodiment. FIG. 7A is a schematic plan view of a main part of an example of a semiconductor device. FIG. 7B is a schematic sectional view taken along a line VIIa-VIIa in FIG. 7A. FIG. 7C is a schematic sectional view taken along a line VIIb-VIIb in FIG. 7A.

A semiconductor device 1B in FIGS. 7A to 7C differs from the semiconductor device 1A (FIGS. 1A to 1C) according to the above first embodiment in that the semiconductor device 1B includes a second frame member 60 between a support 10 and a semiconductor module 20.

For example, at least one of metal, ceramic, and resin materials or a combination of two or more of these kinds is used for the second frame member 60. According to the second embodiment, the semiconductor module 20 includes external connection terminals (a positive terminal, a negative terminal, an output terminal, control terminals, etc.), which extend to the outside and which are not illustrated in FIGS. 7A to 7C. To avoid the electrical connection between these external connection terminals and the second frame member 60, it is suitable to use an insulating material for the second frame member 60.

The second frame member 60 includes a second frame portion 61 on which the semiconductor module 20 is mounted and a second opening portion 62 formed inside the second frame portion 61. On the second frame portion 61, an edge portion 21b of a lower surface 20b located in the opposite direction of an upper surface 20a of the semiconductor module 20 is mounted. A heat transfer medium 30 is disposed between the support 10 and the semiconductor module 20 in the second opening portion 62. The second frame member 60 further includes second insertion holes 63 at portions that connect to the second frame portion 61. The second insertion holes 63 are formed to face screw holes 11 in the support 10 and first insertion holes 43 in a first frame member 40.

The semiconductor module 20 is disposed on the support 10 via the second frame member 60 and the heat transfer medium 30, and the first frame member 40 is disposed on the semiconductor module 20. Next, screws 50 are inserted into the first insertion holes 43 in the first frame member 40 and the second insertion holes 63 in the second frame member 60 and are screwed into the screw holes 11 in the support 10. Because head portions of the screws 50 screwed into the screw holes 11 press the outer edge of the first insertion holes 43, the first frame member 40 is fixed to the support 10.

In the case of the semiconductor device 1B, a first frame portion 41 of the first frame member 40 fixed to the support 10 by the screws 50 outside the semiconductor module 20 presses edge portion 21a of the upper surface 20a of the semiconductor module 20 toward the support 10. In this way, the semiconductor module 20 is fixed to the support 10 via the second frame member 60 and the heat transfer medium 30.

The semiconductor device 1B also provides the same advantageous effects as those provided by the semiconductor device 1A according to the above first embodiment. In the case of the semiconductor device 1B, the second frame member 60 having the second opening portion 62 that communicates with the semiconductor module 20 is disposed between the support 10 and the semiconductor module 20, and the heat transfer medium 30 is disposed in the second opening portion 62. In this way, a certain gap corresponding to the thickness of the second frame member 60 is maintained between the support 10 and the semiconductor module 20, and the heat transfer medium 30 surrounded by the second frame portion 61 is disposed in this gap. Because the semiconductor module 20 is fixed by this second frame member 60 and the first frame member 40 as described above, deformation of the semiconductor module 20 due to heat or the like and resultant pump-out of the heat transfer medium 30 are effectively prevented.

The second embodiment realizes the high-performance and high-quality semiconductor device 1B including the semiconductor module 20 mounted on the support 10 via the heat transfer medium 30.

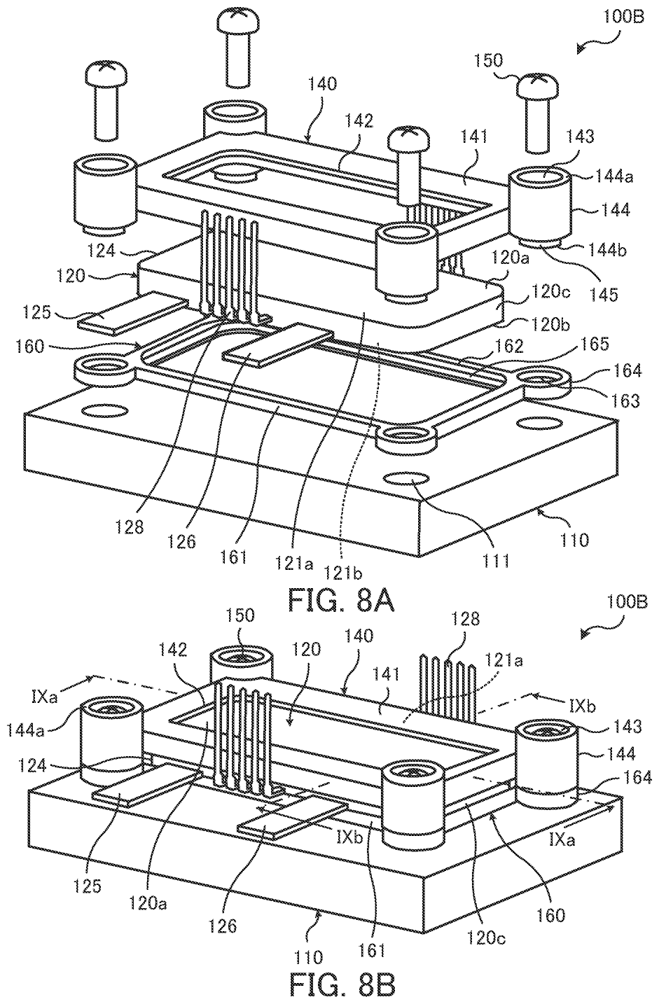

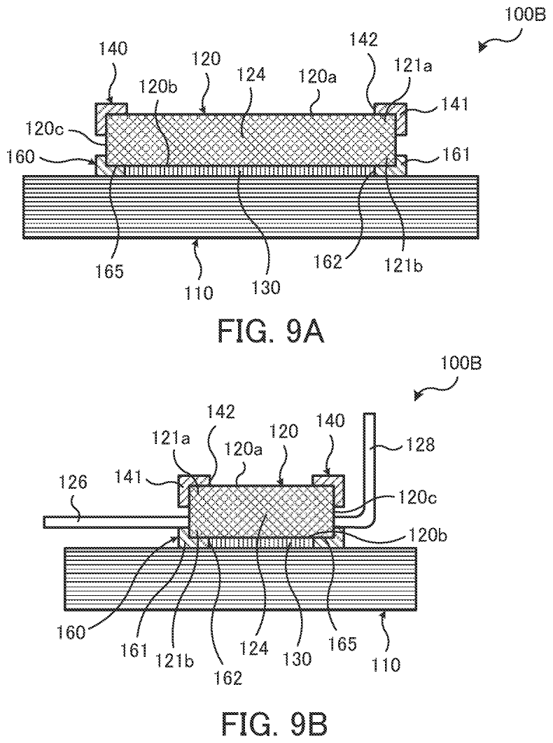

Next, a more specific structure example of the above semiconductor device 1B will be described with reference to FIGS. 8A and 8B and FIGS. 9A and 9B.

FIGS. 8A and 8B and FIGS. 9A and 9B illustrate a structure example of a semiconductor device according to the second embodiment. FIG. 8A is a schematic exploded perspective view of a main part of an example of a semiconductor device. FIG. 8B is a schematic perspective view of the main part of the example of the semiconductor device. FIG. 9A is a schematic sectional view taken along a line IXa-IXa in FIG. 8B. FIG. 9B is a schematic sectional view taken along a line IXb-IXb in FIG. 8B.

A semiconductor device 100B illustrated in FIGS. 8A and 8B differs from the semiconductor device 100A (FIGS. 4A and 4B and FIGS. 5A and 5B) according to the above first embodiment in that the semiconductor device 100B includes a second frame member 160 between the support 110 and the semiconductor module 120 and includes a first frame member 140 that is fitted with the second frame member 160.

The semiconductor module 120 includes the insulated circuit board not illustrated, the resin member 124 that seals the semiconductor chips such as IGBTs mounted on the insulated circuit board, and the positive terminal 125, the negative terminal 126, the output terminal 127, and the control terminals 128 that are electrically connected to the insulated circuit board and the semiconductor chips inside the resin member 124 and that extend to the outside of the resin member 124.

The support 110 has the screw holes 111 outside the resin member 124 of the semiconductor module 120 mounted. The heat transfer medium 130 such as heat radiation grease (FIGS. 9A and 9B) and the second frame member 160 are disposed between the support 110 and the semiconductor module 120 mounted thereon. An insulating material such as a resin or ceramic material is used for the second frame member 160. The second frame member 160 includes a second frame portion 161 on which an edge portion 121b of the lower surface 120b of the semiconductor module 120 is mounted, a second opening portion 162 inside the second frame portion 161, and second fastener portions 164 having second insertion holes 163. The second frame portion 161 has a depressed portion 165 in which part of the lower surface 120b of the semiconductor module 120 mounted, that is, a lower part of the semiconductor module 120, is stored. The second insertion holes 163 in the second frame member 160 are formed to face the screw holes 111 in the support 110.

The first frame member 140 made of a material such as a metal material having certain stiffness is disposed on the semiconductor module 120 mounted on the support 110 via the second frame member 160. The first frame member 140 includes a first frame portion 141 that covers the edge portion 121a of the upper surface 120a of the semiconductor module 120, a first opening portion 142 inside the first frame portion 141, and first fastener portions 144 having first insertion holes 143. The first insertion holes 143 in the first frame member 140 are formed to face the screw holes 111 in the support 110. The outer edge of the first insertion hole 143 around the lower end 144b of the individual first fastener portion 144 of the first frame member 140 has a convex portion 145 (FIG. 8A) that protrudes toward the second frame member 160 and that is fitted with a corresponding second insertion hole 163. The individual second insertion hole 163 is an example of a concave portion that is fitted with a corresponding convex portion 145.

As illustrated in FIGS. 8A and 8B, the semiconductor module 120 is disposed on the support 110 via the second frame member 160 (and the heat transfer medium 130 illustrated in FIGS. 9A and 9B), and the first frame member 140 is disposed on the semiconductor module 120. The convex portions 145 of the first fastener portions 144 are fitted with the second insertion holes 163, which are the concave portions of the second frame member 160, and the first frame member 140 is consequently disposed on the semiconductor module 120. Next, the screws 150 are first inserted into the first insertion holes 143 from above the first frame member 140, are next inserted into the second insertion holes 163 in the second frame member 160, and are finally screwed into the screw holes 111 in the support 110. As a result, the semiconductor device 100B as illustrated in FIG. 8B, that is, the semiconductor device 100B in which the first frame member 140 is fixed to the support 110 via the second frame member 160 (and the heat transfer medium 130 illustrated in FIGS. 9A and 9B) and the semiconductor module 120 is fixed to the support 110 by the first frame member 140, is obtained.

As illustrated in FIGS. 8A and 8B and FIGS. 9A and 9B, in the case of the semiconductor device 100B, the first frame portion 141 of the first frame member 140, the first frame portion 141 covering the edge portion 121a of the semiconductor module 120, has such a shape that covers part of the upper surface 120a and the side surface 120c of the semiconductor module 120 (the resin member 124 thereof). The second frame portion 161, on which the semiconductor module 120 is mounted, of the second frame member 160 has such a shape that covers part of the lower surface 120b and the side surface 120c of the edge portion 121b of the semiconductor module 120. By partly storing the semiconductor module 120 in the depressed portion 165 of the second frame member 160, the location of the semiconductor module 120 with respect to the second frame member 160 is defined.

By disposing the second frame member 160 that covers the lower surface 120b and the side surface 120c of the resin member 124 around the edge portion 121b of the semiconductor module 120 such that the second insertion holes 163 face the screw holes 111 in the support 110, the locations of the second frame member 160 and the semiconductor module 120 with respect to the support 110 are defined. By disposing the first frame member 140 that covers the upper surface 120a and the side surface 120c of the resin member 124 around the edge portion 121a of the semiconductor module 120 such that the first insertion holes 143 face the screw holes 111 in the support 110 and the second insertion holes 163 in the second frame member 160, the location of the first frame member 140 with respect to the support 110, the second frame member 160, and the semiconductor module 120 is defined.

When the screws 150 are screwed into the screw holes 111 via the first insertion holes 143 and the second insertion holes 163, as illustrated in FIG. 8B, the first fastener portions 144 of the first frame member 140 come into contact with the second fastener portions 164 of the second frame member 160 while the first frame portion 141 does not come into contact with the positive terminal 125, the negative terminal 126, the output terminal 127, and the control terminals 128 extending from the side surface 120c of the semiconductor module 120 (FIGS. 8A and 8B and FIGS. 9A and 9B). In a case where an insulating material is used for the second frame member 160, the second frame portion 161 may be disposed to come into contact with the positive terminal 125, the negative terminal 126, the output terminal 127, and the control terminals 128 of the semiconductor module 120.

In the case of the semiconductor device 100B, in the same way as described with the above semiconductor device 1B, the second frame member 160 having the second opening portion 162 that communicates with the semiconductor module 120 is disposed between the support 110 and the semiconductor module 120, and the heat transfer medium 30 is disposed inside the second opening portion 162. Because the semiconductor module 120 is fixed by this second frame member 160 and the first frame member 140 as described above, deformation of the semiconductor module 120 due to heat or the like and resultant pump-out of the heat transfer medium 130 are effectively prevented.

In the case of the semiconductor device 100B, because of the fixing by using the first frame member 140 and the second frame member 160, the stress that occurs in the semiconductor module 120 due to heat or the like is reduced and distributed, and destruction of the semiconductor module 120 is prevented. In addition, obliquely fixing the semiconductor module 120 and occurrence of a resultant defect in the wiring connection are prevented. In addition, in the case of the semiconductor device 100B, for example, displacement of the semiconductor module 120 fixed onto the support 110 via the heat transfer medium 130 such as heat radiation grease and the second frame member 160, torque reduction with respect to the semiconductor module 120, and pump-out of the heat transfer medium 130 are prevented. Thus, deterioration in heat radiation performance and overheat of the semiconductor module 120 are prevented.

In addition, the manufacturing cost of the semiconductor module 120 and the manufacturing cost of the semiconductor device 100B including the semiconductor module 120 are reduced. In the case of the semiconductor device 100B, by using a material such as a metal material having good stiffness for the first frame member 140 so as to enhance the strength of the first frame member 140 and the first fastener portions 144 thereof, the fixing of the first frame member 140 and the semiconductor module 120 to the support 110 is enhanced.

In the above example, the convex portions 145 are formed on the outer edge of the first insertion holes 143 in the first fastener portions 144 of the first frame member 140, and the second insertion holes 163 in the second fastener portions 164 of the second frame member 160 are used as concave portions with which the convex portions 145 are fitted. Alternatively, the outer edge of the second insertion holes 163 in the second fastener portions 164 of the second frame member 160 may be provided with convex portions that protrude toward the first frame member 140, and the first insertion holes 143 in the first fastener portions 144 of the first frame member 140 may be used as concave portions that are fitted with the convex portions.

In addition, the first frame member 140 and the second frame member 160 may additionally be provided with convex portions and concave portions that are fitted therewith at predetermined locations different from the first fastener portions 144 and the second fastener portions 164. That is, one of the first frame member 140 and the second frame member 160 may be provided with a convex portion at a predetermined location, and the other frame member may be provided with a concave portion that is fitted with the convex portion at a predetermined location.

In addition, in the above example, the first frame member 140 and the second frame member 160 are fixed to the support 110 by the screws 150. Alternatively, the first frame member 140 may be fixed to the second frame member 160 by welding, adhesive, or the like, and the second frame member 160 may be fixed to the support 110 by welding, adhesive, or the like.

In addition, as in the example of the semiconductor device 100Aa (FIGS. 6A and 6B) according to the above first embodiment, the circuit board 180 into which the control terminals 128 of the semiconductor module 120 are inserted and which are electrically connected to the control terminals 128 may be disposed on the first frame member 140 of the semiconductor device 100B.

### Third Embodiment

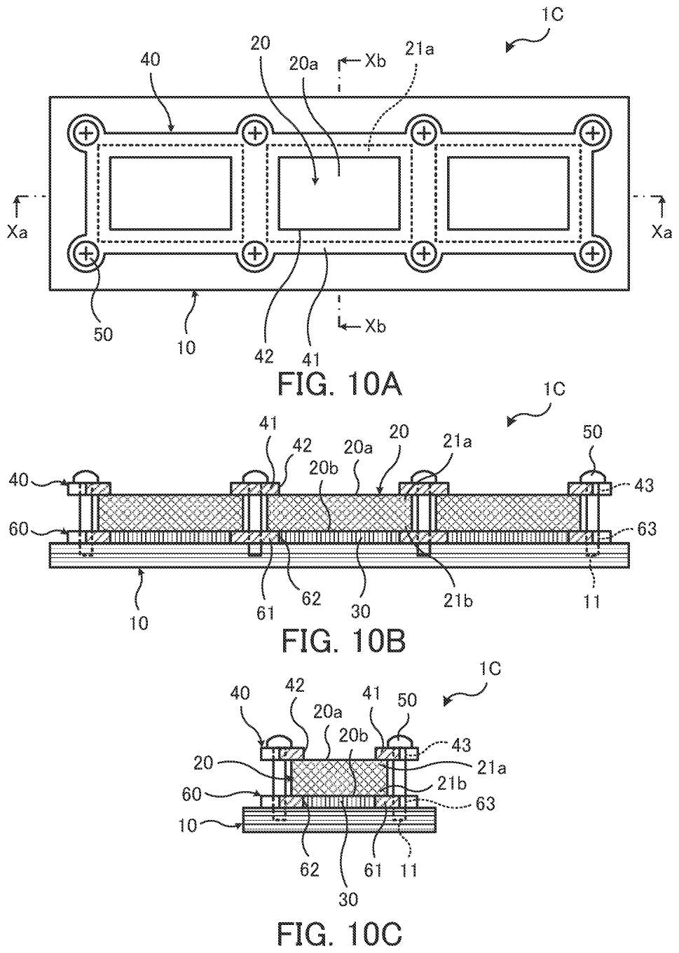

FIGS. 10A to 10C illustrate an example of a semiconductor device according to a third embodiment. FIG. 10A is a schematic plan view of a main part of an example of a semiconductor device. FIG. 10B is a schematic sectional view taken along a line Xa-Xa in FIG. 10A. FIG. 10C is a schematic sectional view taken along a line Xb-Xb in FIG. 10A.

A semiconductor device 1C illustrated in FIGS. 10A to 10C differs from the semiconductor device 1B (FIGS. 7A to 7C) according to the second embodiment in that the semiconductor device 1C includes a first frame member 40 and a second frame member 60 sandwiching a plurality of semiconductor modules 20, e.g., three semiconductor modules 20 in FIGS. 10A to 10C.

This group of semiconductor modules 20 are aligned in one direction and are mounted on the support 10, for example. The second frame member 60 is disposed between the support 10 and the group of semiconductor modules 20, and the first frame member 40 is disposed on the group of semiconductor modules 20.

The second frame member 60 of the semiconductor device 1C includes a second frame portion 61 on which the edge portion 21b of the lower surface 20b of each semiconductor module 20 is mounted, second opening portions 62, each of which is formed inside the second frame portion 61 and communicates with the lower surface 20b of a corresponding one of the semiconductor modules 20, and second insertion holes 63 into which screws 50 are inserted. A heat transfer medium 30 such as heat radiation grease is disposed inside each second opening portion 62 of the second frame member 60. In addition, the first frame member 40 of the semiconductor device 1C includes a first frame portion 41 that covers the edge portion 21a of the upper surface 20a of each semiconductor module 20, first opening portions 42, each of which is formed inside the first frame portion 41 and communicates with the upper surface 20a of a corresponding one of the semiconductor modules 20, and first insertion holes 43 into which the screws 50 are inserted. The second insertion holes 63 in the second frame member 60 and the first insertion holes 43 in the first frame member 40 are formed to face screw holes 11 in the support 10.

The semiconductor modules 20 are disposed on the support 10 via the second frame member 60 and the heat transfer medium 30, and the first frame member 40 is disposed on the semiconductor modules 20. Next, the screws 50 are inserted into the first insertion holes 43 in the first frame member 40 and the second insertion holes 63 in the second frame member 60 and are screwed into the screw holes 11 in the support 10. As a result, the semiconductor device 1C as illustrated in FIGS. 10A to 10C is obtained.

As described with the semiconductor device 1C, by using the first frame member 40 and the second frame member 60 having a shape corresponding to a plurality of semiconductor modules 20, the group of semiconductor modules 20 may be fixed to the support 10. Alternatively, by using only the first frame member 40 having a shape corresponding to the plurality of semiconductor modules 20, the semiconductor modules 20 may be fixed to the support 10.

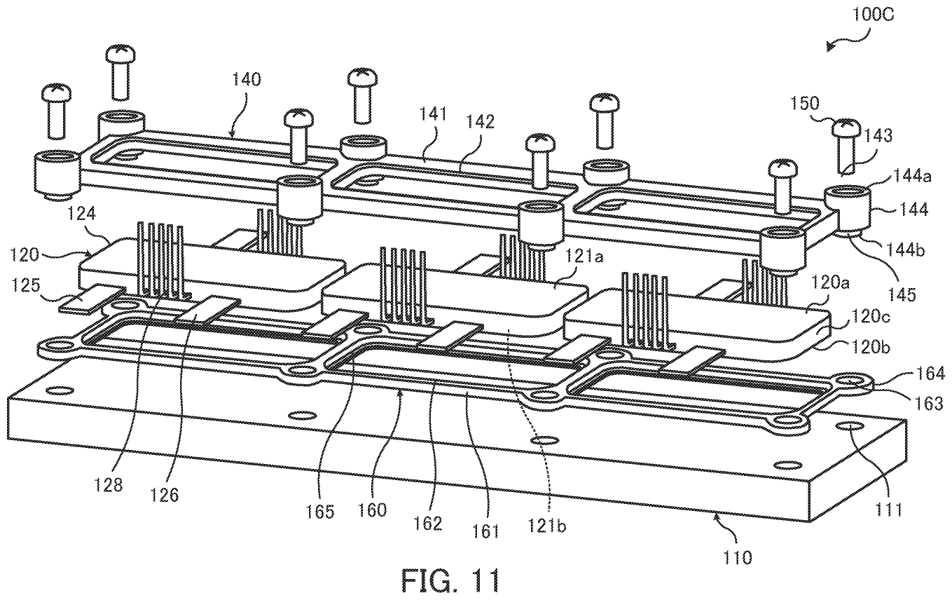

Next, a more specific structure example of the semiconductor device 1C as described above will be described with reference to FIG. 11.

FIG. 11 illustrates a structure example of a semiconductor device according to the third embodiment. FIG. 11 is a schematic exploded perspective view of a main part of an example of a semiconductor device.

A semiconductor device 100C illustrated in FIG. 11 differs from the semiconductor device 100B (FIGS. 8A and 8B and FIGS. 9A and 9B) according to the above second embodiment in that the semiconductor device 100C includes a first frame member 140 and a second frame member 160 sandwiching three semiconductor modules 120.

For example, each of the three semiconductor modules 120 may be a so-called 2-in-1 IGBT module including a group of semiconductor chips that constitute upper and lower arms in a power conversion apparatus. The semiconductor device 100C is an example of a so-called three-phase inverter including three semiconductor modules 120 of the U phase, the V phase, and the W phase.

The second frame member 160 has a second frame portion 161 on which the edge portion 121b of the lower surface 120b of each semiconductor module 120 is mounted, second opening portions 162, each of which is formed inside the second frame portion 161 and communicates with the lower surface 120b of a corresponding one of the semiconductor modules 120, and second fastener portions 164 having second insertion holes 163. The second frame portion 161 has a depressed portion 165 in which part of the lower surface 120b of each semiconductor module 120 mounted is stored. The second insertion holes 163 in the second frame member 160 are formed to face screw holes 111 in the support 110.

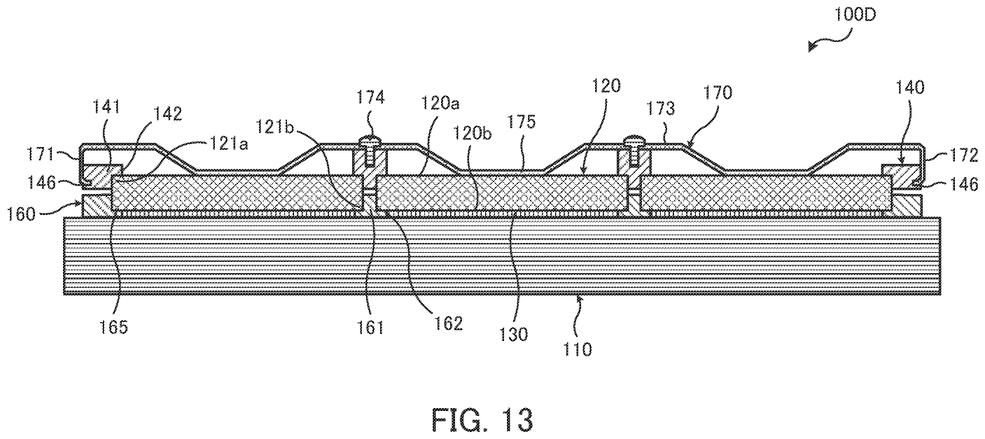

The first frame member 140 is disposed on the group of semiconductor modules 120 mounted on the support 110 via the second frame member 160 (and an individual heat transfer medium (corresponding to an individual heat transfer medium 130 in FIG. 13 to be described below)). The first frame member 140 has a first frame portion 141 that covers the edge portion 121a of the upper surface 120a of each semiconductor module 120, first opening portions 142, each of which is formed inside the first frame portion 141 and communicates with the upper surface 120a of a corresponding one of the semiconductor modules 120, and first fastener portions 144 having first insertion holes 143. The first insertion holes 143 in the first frame member 140 are formed to face the screw holes 111 in the support 110. The outer edge of the first insertion hole 143 around a lower end 144b of the individual first fastener portion 144 of the first frame member 140 has a convex portion 145 that is fitted with a corresponding one of the second insertion holes 163 (concave portions) in the second frame member 160.

As illustrated in FIG. 11, the group of semiconductor modules 120 is disposed on the support 110 via the second frame member 160 (and the individual heat transfer medium), and the first frame member 140 is disposed on the semiconductor modules 120. The convex portions 145 of the first fastener portions 144 are fitted with the second insertion holes 163 in the second frame member 160, and the first frame member 140 is consequently disposed on the group of semiconductor modules 120. Next, screws 150 are first inserted into the first insertion holes 143 from above the first frame member 140, are next inserted into the second insertion holes 163 in the second frame member 160, and are finally screwed into the screw holes 111 in the support 110. As a result, the semiconductor device 100C is obtained.

In the case of the semiconductor device 100C, the first frame portion 141 of the first frame member 140, the first frame portion 141 covering the edge portion 121a of each semiconductor module 120, has such a shape that covers part of the upper surface 120a and the side surface 120c of each semiconductor module 120 (the resin member 124 thereof). The second frame portion 161, on which each semiconductor module 120 is mounted, of the second frame member 160 has such a shape that covers part of the lower surface 120b and the side surface 120c of the edge portion 121b of each semiconductor module 120. By partly storing each semiconductor module 120 in the depressed portion 165 of the second frame member 160, the location of each semiconductor module 120 with respect to the second frame member 160 is defined.

By disposing the second frame member 160 that covers the lower surface 120b and the side surface 120c of the resin member 124 around the edge portion 121b of each of the group of semiconductor modules 120 such that the second insertion holes 163 face the screw holes 111 in the support 110, the locations of the group of semiconductor modules 120 and the second frame member 160 with respect to the support 110 are defined. By disposing the first frame member 140 that covers the upper surface 120a and the side surface 120c of the resin member 124 around the edge portion 121a of each of the group of semiconductor modules 120 such that the first insertion holes 143 face the screw holes 111 in the support 110 and the second insertion holes 163 in the second frame member 160, the location of the first frame member 140 with respect to the support 110, the second frame member 160, and the semiconductor modules 120 is defined.

In the case of the semiconductor device 100C, by using the first frame member 140 and the second frame member 160 having a shape corresponding to the plurality of semiconductor modules 120, the group of semiconductor modules 120 is mounted on the support 110 without being displaced. In addition, in the case of the semiconductor device 100C, for example, displacement of the group of semiconductor modules 120, torque reduction with respect to the group of semiconductor modules 120, and pump-out of the individual heat transfer medium disposed between the corresponding semiconductor module 120 and the support 110 are prevented. Thus, deterioration in heat radiation performance and overheat of the group of semiconductor modules 120 are prevented. In addition, the semiconductor device 100C also provides the same advantageous effects as those provided by the above semiconductor device 100B.

In the above example, the first frame member 140 and the second frame member 160 are fixed to the support 110 by the screws 150. Alternatively, the first frame member 140 may be fixed to the second frame member 160 by welding, adhesive, or the like, and the second frame member 160 may be fixed to the support 110 by welding, adhesive, or the like.

In addition, in the above example, the semiconductor module 120 is fixed to the support 110 by using both the first frame member 140 and the second frame member 160. However, the semiconductor module 120 may be fixed to the support 110 by using only the first frame member 140.

In addition, as in the example of the semiconductor device 100Aa (FIGS. 6A and 6B) according to the above first embodiment, the circuit board 180 into which the control terminals 128 of the group of semiconductor modules 120 are inserted and which is electrically connected to the control terminals 128 may be disposed on the first frame member 140 of the semiconductor device 100C.

### Fourth Embodiment

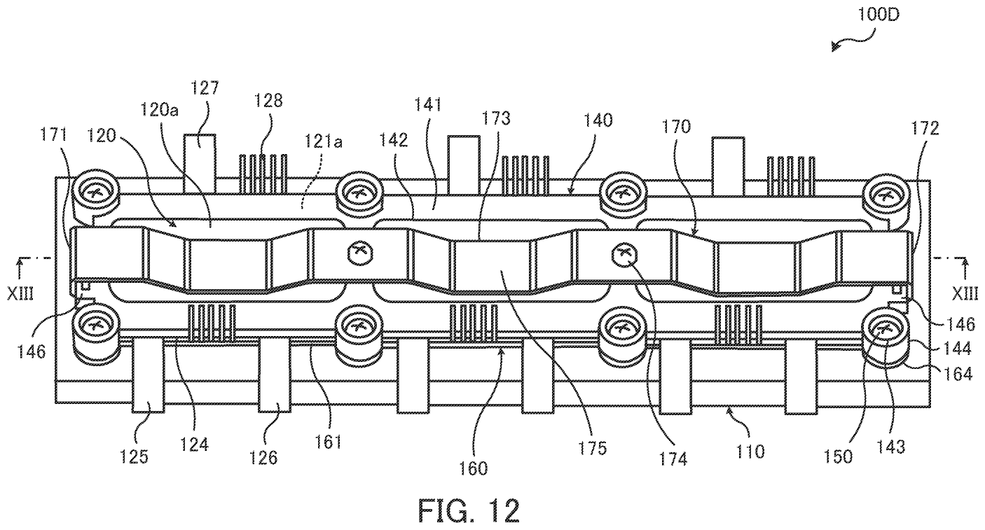

FIGS. 12 and 13 illustrate a structure example of a semiconductor device according to a fourth embodiment. FIG. 12 is a schematic perspective view of a main part of an example of a semiconductor device. FIG. 13 is a schematic sectional view taken along a line XIII-XIII in FIG. 12.

A semiconductor device 100D illustrated in FIGS. 12 and 13 differs from the above semiconductor device 100C (FIG. 11) according to the above third embodiment in that a beam member 170 is attached to a first frame member 140.

The first frame member 140 has engaging portions 146 at opposite outer edge portions of a first frame portion 141. The beam member 170 is shaped by bending a belt-like plate material such as a metal material having certain stiffness at predetermined locations. One end portion 171 and another end portion 172 (two end portions) of the beam member 170 are engaged with the engaging portions 146 of the first frame member 140, and the beam member 170 is consequently fixed to the first frame member 140. The beam member 170 is disposed to extend over the three semiconductor modules 120 and fixed to the first frame portion 141 by screws 174, each of which is located at an individual location between two neighboring semiconductor modules 120. A pressing structure 175 is formed at an individual first opening portion 142 in the first frame member 140 at an intermediate portion 173 between the end portions 171 and 172 of the beam member 170. Each pressing structure 175 presses the upper surface 120a of a corresponding semiconductor module 120 exposed in a corresponding first opening portion 142. In the example in FIG. 12, the individual pressing structure 175 is formed by bending the beam member 170 and functions as a plate spring.

The first frame member 140 to which the beam member 170 is attached is disposed on the group of semiconductor modules 120 and is fixed to the support 110 via the second frame member 160 and the heat transfer medium 130 (FIG. 13) by screws 150. Alternatively, after the first frame member 140 is disposed on the group of semiconductor modules 120 and fixed to the support 110 via the second frame member 160 and the heat transfer medium 130 (FIG. 13) by the screws 150, the beam member 170 is attached to the first frame member 140. In this way, the upper surface 120a of the individual semiconductor module 120 is pressed toward the support 110 by a corresponding pressing structure 175 that functions as a plate spring of the beam member 170. As a result, the pressing of the individual semiconductor module 120 toward the heat transfer medium 130 and the support 110 is enhanced, and the heat radiation performance is consequently improved. In addition, the location of the individual semiconductor module 120 sandwiched between the first frame member 140 and the second frame member 160 is stabilized, displacement of the individual semiconductor module 120 is prevented, and the vibration durability is improved.

In this example, the beam member 170 having the individual pressing structure 175 pressing the upper surface 120a of a corresponding semiconductor module 120 is attached to the first frame member 140 having a shape corresponding to the three semiconductor modules 120. Alternatively, the beam member 170 having a pressing structure 175 pressing the upper surface 120a of a single semiconductor module 120 may be attached to the first frame member 140 having a shape corresponding to the single semiconductor module 120, that is, to the first frame member 140 according to the above first and second embodiments.

In addition, as in the example of the semiconductor device 100Aa (FIGS. 6A and 6B) according to the above first embodiment, the circuit board 180 into which the control terminals 128 of the semiconductor modules 120 are inserted and which is electrically connected to the control terminals 128 may be disposed on the first frame member 140 of the semiconductor device 100D.

### Fifth Embodiment

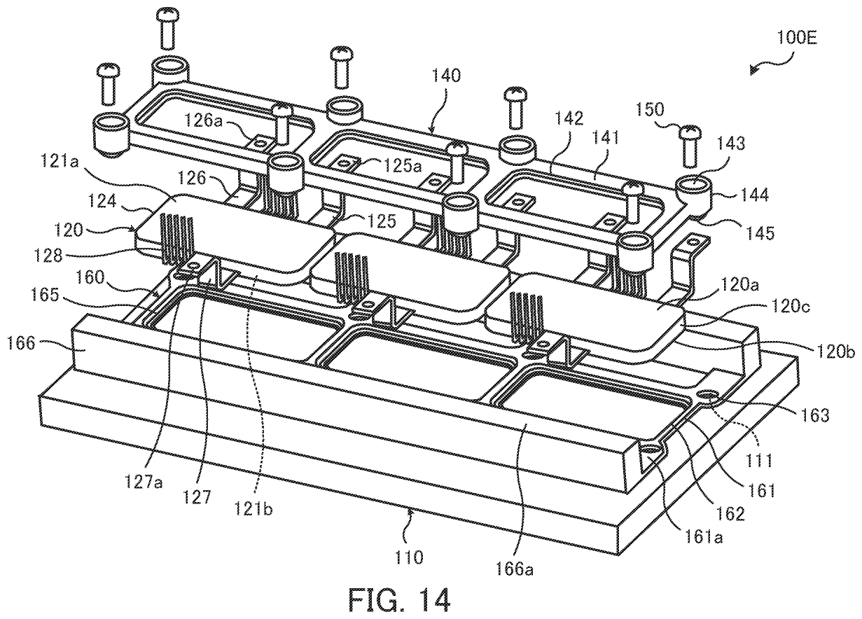

FIG. 14 illustrates a structure example of a semiconductor device according to a fifth embodiment. FIG. 14 is a schematic exploded perspective view of a main part of an example of a semiconductor device.

A semiconductor device 100E illustrated in FIG. 14 differs from the semiconductor device 100C (FIG. 11) according to the above third embodiment in that a second frame member 160 including terminal blocks 166 is used.

The terminal blocks 166 of the second frame member 160 of the semiconductor device 100E are integrally formed with a second frame portion 161 outside the second frame portion 161. The terminal blocks 166 are shaped such that, when the second frame member 160 is disposed on the support 110, an upper surface 166a of the individual terminal block 166 is located above an upper surface 161a of the second frame portion 161.

Each of the group of semiconductor modules 120 of the semiconductor device 100E is shaped (crank shape) such that the positive terminal 125, the negative terminal 126, and the output terminal 127 extend from the side surface 120c of the semiconductor module 120 toward the outside of the second frame portion 161, are bent and extend in the upward direction of the semiconductor module 120, and are bent and extend in lateral directions of the semiconductor module 120. The positive terminal 125, the negative terminal 126, and the output terminal 127 are bent to fit the shape of the terminal blocks 166. The positive terminal 125, the negative terminal 126, and the output terminal 127 are previously bent such that a tip portion 125a, a tip portion 126a, and a tip portion 127a of these terminals are located on the upper surface 166a of the terminal blocks 166 when the semiconductor module 120 is mounted on the second frame member 160.

As illustrated in FIG. 14, the group of semiconductor modules 120 is disposed on the support 110 via the second frame member 160, and the first frame member 140 is disposed on the semiconductor modules 120. The convex portions 145 of the first fastener portions 144 of the first frame member 140 are fitted with the second insertion holes 163 (concave portions) of the second frame member 160, and the first frame member 140 is consequently disposed on the group of semiconductor modules 120. Next, from above the first frame member 140, the screws 150 are inserted into the first insertion holes 143 and the second insertion holes 163 in the second frame member 160 and screwed into the screw holes 111 in the support 110. In this way, the semiconductor device 100E is obtained.

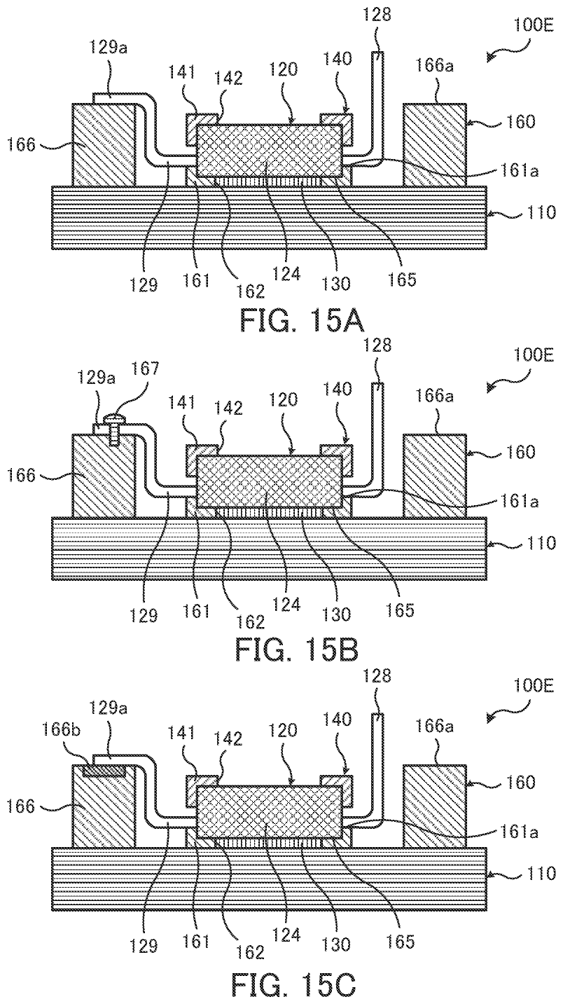

FIGS. 15A to 15C each illustrate an example of the connection between an external connection terminal and a terminal block of the semiconductor device according to the fifth embodiment. FIGS. 15A to 15C are each a schematic sectional view of a main part of an example of the semiconductor device in which an external connection terminal and a terminal block are connected.

As illustrated in FIGS. 15A to 15C, an external connection terminal 129 of the individual semiconductor module 120 (the positive terminal 125, the negative terminal 126, or the output terminal 127) is previously bent to fit the shape of a corresponding terminal block 166 of the second frame member 160, and a tip portion 129a (the tip portion 125a, the tip portion 126a, or the tip portion 127a) is located on the upper surface 166a of the terminal block 166 when the semiconductor module 120 is mounted on the second frame member 160.

For example, as illustrated in FIG. 15A, the tip portion 129a of the external connection terminal 129 of the semiconductor module 120 is mounted on the upper surface 166a of the terminal block 166. Alternatively, as illustrated in FIG. 15B, the tip portion 129a of the external connection terminal 129 of the semiconductor module 120 may be fixed to the upper surface 166a of the terminal block 166 by a screw 167. Still alternatively, as illustrated in FIG. 15C, an electrically conductive terminal portion 166b may be formed on the upper surface 166a of the terminal block 166, and the tip portion 129a of the external connection terminal 129 of the semiconductor module 120 may be electrically connected to this terminal portion 166b. For example, the tip portion 129a may be bonded to the terminal portion 166b by using bonding material such as solder. Alternatively, the tip portion 129a may be fastened to the terminal portion 166b by using a screw. Still alternatively, the tip portion 129a may be welded to the terminal portion 166b by laser welding.

As in the case of the semiconductor device 100E, by using the second frame member 160 having the terminal blocks 166, the tip portion 125a, the tip portion 126a, and the tip portion 127a of the positive terminal 125, the negative terminal 126, and the output terminal 127 of the individual semiconductor module 120 (the tip portion 129a of the external connection terminal 129), each of the terminals being bent in a predetermined shape, may be connected to the terminal blocks 166.

In this example, the terminal blocks 166 are formed on the second frame member 160 having a shape corresponding to the three semiconductor modules 120, and the tip portion 125a, the tip portion 126a, and the tip portion 127a of the positive terminal 125, the negative terminal 126, and the output terminal 127 of the individual semiconductor module 120 are connected to the terminal blocks 166. Alternatively, the second frame member 160 having a shape corresponding to a single semiconductor module 120, that is, the second frame member 160 according to the above first and second embodiments may be provided with the terminal blocks 166 outside the second frame portion 161, and the tip portion 125a, the tip portion 126a, and the tip portion 127a of the positive terminal 125, the negative terminal 126, and the output terminal 127 of this single semiconductor module 120 may be connected to the terminal blocks 166.

In addition, when the second frame member 160 having the terminal blocks 166 is used, the beam member 170 according to the above fourth embodiment may be attached to the first frame member 140 used in combination with the second frame member 160, and in this way, the semiconductor modules 120 are pressed toward the support 110 by the pressing structures 175.

In addition, as in the example of the semiconductor device 100Aa (FIGS. 6A and 6B) according to the above first embodiment, the circuit board 180 into which the control terminals 128 of the semiconductor modules 120 are inserted and which is electrically connected to the control terminals 128 may be disposed on the first frame member 140 of the semiconductor device 100E.

Next, an example of a semiconductor device manufacturing method will be described as a sixth embodiment.

### Sixth Embodiment

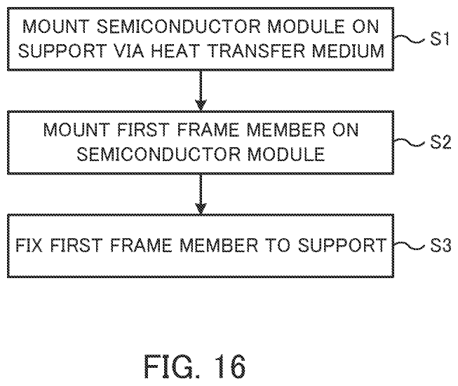

FIG. 16 illustrates an example of a semiconductor device manufacturing method according to a sixth embodiment.

For example, to manufacture the semiconductor device 100A (FIGS. 4A and 4B and FIGS. 5A and 5B) according to the above first embodiment, first, a mounting step of mounting the semiconductor module 120 on the support 110 via the heat transfer medium 130 is performed (step S1). In this step, for example, the heat transfer medium 130 such as heat radiation grease is disposed on a predetermined mounting area that is set on the inner side of the screw holes 111 in the support 110, and the semiconductor module 120 is mounted on the heat transfer medium 130. Alternatively, the semiconductor module 120 having the lower surface 120b on which the heat transfer medium 130 is already disposed is mounted on the predetermined mounting area on the support 110.

Next, a first mounting step of mounting the first frame member 140 on the semiconductor module 120 is performed (step S2). In this step, for example, the first frame member 140 is mounted on the semiconductor module 120 such that the first insertion holes 143 face the screw holes 111 in the support 110 and such that the edge portion 121a of the upper surface 120a of the semiconductor module 120 (the resin member 124 thereof) is covered by the first frame portion 141.

Next, a fixing step of fixing the first frame member 140 to the support 110 is performed (step S3). In this step, for example, the screws 150 are inserted into the first insertion holes 143 in the first frame member 140, and the tip portions of the screws 150 are screwed into the screw holes 111 in the support 110. As a result, the first frame member 140 is fixed to the support 110.

The semiconductor device 100A is manufactured in accordance with the method as described above.

In addition, to manufacture the semiconductor device 100B (FIGS. 7A to 7C) additionally including the second frame member 160 according to the above second embodiment, before the mounting step in step S1, a second mounting step of mounting the second frame member 160 on the support 110 is performed. The mounting step in step S1 and the first mounting step in step S2 are performed after the second mounting step. In the fixing step in step S3, the first frame member 140 is fixed to the support 110 via the second frame member 160.

In addition, the semiconductor device 100C (FIG. 11) according to the third embodiment including a plurality of semiconductor modules 120 and the first frame member 140 having a shape corresponding to the semiconductor modules 120 or additionally including the second frame member 160 may be manufactured in the same procedure as described above.

In addition, to manufacture the semiconductor device 100D (FIGS. 12 and 13) including the beam member 170 according to the above fourth embodiment, for example, before the first mounting step in step S2, the beam member 170 is attached to the first frame member 140 to be mounted on the semiconductor module 120. Alternatively, after the fixing step in step S3, the beam member 170 is attached to the first frame member 140 fixed to the support 110.

In addition, to manufacture the semiconductor device 100E (FIG. 14 and FIGS. 15A to 15C) including the second frame member 160 having the terminal blocks 166 according to the above fifth embodiment, before the mounting step in step S1, a second mounting step of mounting the second frame member 160 having the terminal blocks 166 on the support 110 is performed. Next, for example, after the fixing step in step S3, a connection step of connecting the tip portion 125a, the tip portion 126a, and the tip portion 127a of the positive terminal 125, the negative terminal 126, and the output terminal 127 that bend and extend from the semiconductor module 120 to the terminal blocks 166 is performed.

The semiconductor devices 100A, 100B, 100C, 100D, and 100E are manufactured by using the methods as described above.

To dispose the circuit board 180 (FIGS. 6A and 6B) according to the first embodiment on the semiconductor device 100A, 100B, 100C, 100D, or 100E, the circuit board 180 is disposed on the first frame member 140 such that the control terminals 128 of the individual semiconductor module 120 are inserted into the circuit board 180 and are electrically connected to the circuit board 180.

In one aspect, a high-performance and high-quality semiconductor device including a semiconductor module mounted on a support via a heat transfer medium is manufactured.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that various changes, substitutions, and alterations could be made hereto without departing from the spirit and scope of the invention.

What is claimed is:

1. A semiconductor device, comprising:
a support;
a semiconductor module mounted on the support, the semiconductor module including a semiconductor chip and a resin member that seals the semiconductor chip;
a heat transfer medium disposed between the support and the semiconductor module; and
a first frame member disposed on the semiconductor module, the first frame member having:
a first frame portion that covers an edge portion of an upper surface of the resin member, the first frame member being fixed to the support; and
a first opening portion that is formed in the first frame portion, and through which the resin member is exposed.

2. The semiconductor device according to claim 1,
wherein the support has a screw hole, which is formed outside the resin member of the semiconductor module in a top view of the semiconductor device,
wherein the first frame member has a first insertion hole which is formed to face the screw hole, and
wherein the semiconductor device further includes a screw that is inserted into the first insertion hole and screwed into the screw hole, to thereby fix the first frame member to the support.

3. The semiconductor device according to claim 1, further comprising a second frame member disposed between the support and the semiconductor module, the second frame member having
a second frame portion on which the semiconductor module is mounted, and
a second opening portion, which is formed in the second frame portion and in which the heat transfer medium is disposed,
wherein the first frame member is fixed to the support via the second frame member.

4. The semiconductor device according to claim 3,
wherein the support has a screw hole, which is formed outside the resin member of the semiconductor module in a top view of the semiconductor device,
wherein the first frame member has a first insertion hole which is formed to face the screw hole, and
wherein the second frame member has a second insertion hole which is formed to face the screw hole and the first insertion hole, and
wherein the semiconductor device further includes a screw that is inserted into the first insertion hole and the second insertion hole and screwed into the screw hole, to thereby fix the first frame member to the support via the second frame member.

5. The semiconductor device according to claim 3,
wherein the second frame member further has a terminal block formed outside the second frame portion in a top view of the semiconductor device, and
wherein the semiconductor module further includes an external connection terminal which is electrically connected to the semiconductor chip, which extends from the resin member toward an outside of the second frame portion in the top view, and which is connected to the terminal block.

6. The semiconductor device according to claim 3, wherein the second frame portion has a depressed portion for accommodating a part of the semiconductor module mounted thereon.

7. The semiconductor device according to claim 3, wherein
one of the first frame member and the second frame member has a convex portion which protrudes toward the other of the first frame member and the second frame member, said the other frame member having a concave portion which is depressed and is fitted with the convex portion.

8. The semiconductor device according to claim 1, further comprising a beam member which has:
two end portions that engage with the first frame portion, and
an intermediate portion between the two end portions, the intermediate portion being located in the first opening portion and pressing the resin member in the first opening portion toward the support.

9. The semiconductor device according to claim 1, further comprising a circuit board disposed on a surface of the first frame member, the surface and the support being on opposite sides of the first frame member, the circuit board being electrically connected to the semiconductor module.

10. The semiconductor device according to claim 1,
wherein the semiconductor module is provided in plurality,
wherein the first frame portion of the first frame member covers the edge portion of the upper surface of the resin member of each of the plurality of semiconductor modules, and
wherein the first opening portion of the first frame member is provided in plurality, each first opening portion being formed in the first frame portion, and exposing one of the resin members of the plurality of semiconductor modules.

11. A semiconductor device manufacturing method, comprising:
mounting a semiconductor module which has a semiconductor chip and a resin member that seals the semiconductor chip on a support via a heat transfer medium;
mounting a first frame member which has a first frame portion to cover an edge portion of an upper surface of the resin member, the first frame member having a first opening portion formed in the first frame portion, the resin member of the semiconductor module being exposed from the first opening portion; and
fixing the first frame member to the support.

12. The semiconductor device manufacturing method according to claim 11, further comprising:
providing a second frame member having a second frame portion and a second opening portion formed in the second frame portion,
mounting the second frame member between the support and the semiconductor module, such that the semiconductor module is mounted on the second frame portion, and the heat transfer medium is disposed in the second opening portion,
wherein the fixing of the first frame member to the support includes fixing the first frame member to the support via the second frame member.

13. The semiconductor device manufacturing method according to claim 12,
wherein the semiconductor module further includes an external connection terminal, which is electrically connected to the semiconductor chip and which extends from the resin member toward an outside of the second frame portion in a top view of the semiconductor device,
wherein the second frame member further has a terminal block formed outside the second frame portion in the top view, and
wherein the method further includes connecting the external connection terminal to the terminal block.

14. The semiconductor device manufacturing method according to claim 11, further comprising:
providing a beam member that has two end portions and an intermediate portion between the two end portions,
mounting the beam member so that the intermediate portion is located in the first opening portion, and
engaging the two end portions of the beam member with the first frame portion such that the intermediate portion presses the resin member in the first opening portion toward the support.
